(19) United States
(12) Patent Application Publication
(10) Pub. No.: US 2018/0052343 A1
(43) Pub. Date: Feb. 22, 2018

(54) ARRAY SUBSTRATE AND DISPLAY DEVICE

(71) Applicants: Shenzhen China Star Optoelectronics Technology Co. Ltd., Shenzhen (CN); Wuhan China Star Optoelectronics Technology Co. Ltd., Wuhan (CN)

(72) Inventor: XING MING, Shenzhen (CN)

(73) Assignees: Shenzhen China Star Optoelectronics Technology Co. Ltd., Shenzhen (CN); Wuhan China Star Optoelectronics Technology Co. Ltd., Wuhan (CN)

(21) Appl. No.: 14/897,730

(22) PCT Filed: Sep. 24, 2015
(86) PCT No.: PCT/CN2015/090485

§ 371 Date: Sep. 27, 2017

(30) Foreign Application Priority Data
Aug. 26, 2015 (CN) 201510527004.X

(51) Int. Cl. G02F 1/1339; H01L 27/12; H01L 23/31; G02F 1/1362

(52) U.S. Cl. CPC G02F 1/1339; H01L 27/124; G02F 1/1368; G02F 1/136209; G02F 1/136286; H01L 23/3142

(57) ABSTRACT

Disclosed are an array substrate and a display device which belong to the technical field of display and are intended to solve the technical problem of undesirable display effect resulting from transparent conductive material left in a gap of an overcoat layer.

### CROSS-REFERENCE TO RELATED APPLICATIONS

The present application claims the priority of Chinese patent application CN201510527004.X, entitled “Array substrate and display device” and filed on Aug. 26, 2015, the entirety of which is incorporated herein by reference.

### TECHNICAL FIELD

The present disclosure relates to the technical field of display, and in particular, to an array substrate and a display device.

### TECHNICAL BACKGROUND

With the widespread use of mobile devices in real life, users are now requiring increasingly more about the display effect of mobile devices. To meet users' requirements, display screens of mobile devices are now being produced with better display quality and higher resolution, and are becoming lighter, thinner, and less power consuming. However, when the resolution of a mobile device is improved, the aperture ratio thereof will be reduced. Hence, in order to ensure desirable display brightness of a mobile device, the mobile device should be provided with higher backlight brightness. In an existing mobile device, the brightness of a backlight source has become higher than that of a larger display device like TV. However, the higher brightness of a backlight source will increase the power consumption of a mobile device, and shortens the standby time of the mobile device, which, obviously, is not wanted by users.

In order to enable the display screen of a mobile device to have a desirable brightness without increasing the power consumption of its backlight source, it is necessary to improve light transmittance of the display screen of the mobile device.

According to a conventional method, the light transmittance can be improved by decreasing the capacitance between a pixel electrode and a data line/scan line, and between a common electrode and a data line/scan line through an overcoat layer usually having a thickness of over 1.5 μm. By providing the overcoat layer, the aperture ratio of a display screen can be improved. In addition, to meet the requirement for a narrow-bezel display screen, the width of a sealant is usually reduced, which, however, may decrease adhesion strength of the sealant to an array substrate and a substrate assembled together with the array substrate, thereby resulting in a potential problem in the display screen.

In order to ensure the adhesion strength of the sealant to the array substrate and the substrate assembled together with the array substrate, as shown in FIGS. 1 and 2, a gap is usually formed on the overcoat layer 1 on the periphery of the array substrate, for matching the sealant. This gap can guarantee a contact area between the sealant and the array substrate and therefore the adhesion strength of the sealant. However, the gap of the overcoat layer is usually deep and may expose some of data lines 3, and slopes of the gap usually incline at over 50 degrees. Thus, when a common electrode and a common electrode are formed in a following procedure, a large amount of transparent conductive material 2 may be left in the gap. The transparent conductive material 2 may probably lead to a short circuit between the data lines 3, thereby resulting in undesirable display.

### SUMMARY OF THE INVENTION

The objective of the present disclosure is to provide an array substrate and a display device, for solving the technical problem of potential short circuits resulting from transparent conductive material left in a gap of an overcoat layer.

The present disclosure, at one aspect, provides an array substrate which comprises data lines and an overcoat layer located above the data lines. In a non-display area of the array substrate, a gap is formed in the overcoat layer, for matching a sealant. A color barrier layer covering the data lines is formed in the gap, the color barrier layer having a surface lower than a surface of the overcoat layer.

Alternatively, the color barrier layer is located between the overcoat layer and the data lines.

Alternatively, the color barrier layer and the overcoat layer are located at a same layer on the data lines.

Alternatively, the array substrate further comprises, at a position corresponding to the gap of the overcoat layer, and between the data lines and a base substrate, from bottom to top, a buffer layer, a gate insulator layer, and an inter level dielectric layer.

Alternatively, the color barrier layer comprises at least one of a red color barrier layer, a green color barrier layer, a blue color barrier layer, and a colourless color barrier layer.

Alternatively, the surface of the color barrier layer is at least 0.5 um lower than that of the overcoat layer.

Alternatively, the color barrier layer has a thickness of ranging from 1 μm to 5 μm.

Alternatively, the overcoat layer has a thickness ranging from 1 μm to 6 μm.

The present disclosure is able to bring the following beneficial effects. According to the present disclosure, the data lines located at the gap are provided thereon with the insulative color barrier layer. The color barrier layer covers said data lines and isolates the transparent conductive material left in the gap totally from said data lines, thus preventing said transparent conductive material from causing a short circuit between said data lines after a common electrode and a pixel electrode are formed, thereby guaranteeing the display effect of the display device.

The present disclosure, at another aspect, provides a display device which comprises the above array substrate and a color filter substrate assembled together with the array substrate.

Other features and advantages of the present disclosure will be further explained in the following description, and will partly become self-evident therefrom, or be understood through the implementation of the present disclosure. The objectives and advantages of the present disclosure will be achieved through the structures specifically pointed out in the description, claims, and the accompanying drawings.

### BRIEF DESCRIPTION OF THE DRAWINGS

For further illustrating the technical solutions provided in the embodiments of the present disclosure, a brief introduction will be given below to the accompanying drawings involved in the embodiments.

FIG. 1 schematically shows the structure of an array substrate according to the existing technologies;

FIG. 2 schematically shows a sectional view of a part of the array substrate along line A-A in FIG. 1;

FIG. 3 schematically shows the structure of an array substrate according to the embodiment of the present disclosure;

FIG. 4 schematically shows a sectional view of a part of the array substrate along line B-B in FIG. 3; and

FIG. 5 schematically shows another sectional view of the part of the array substrate along line B-B in FIG. 3.

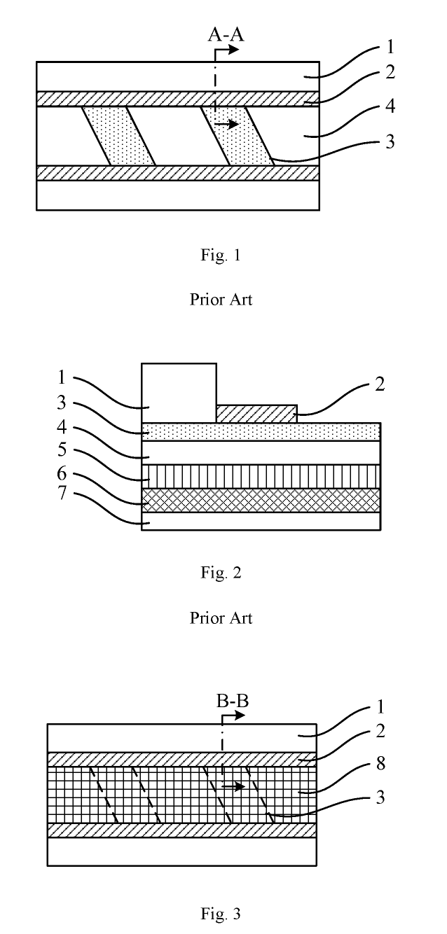

### DETAILED DESCRIPTION OF THE EMBODIMENTS

The present disclosure will be explained in detail below with reference to the embodiments and the accompanying drawings, so that one can fully understand how the present disclosure solves the technical problem and achieves the technical effects through the technical means, thereby implementing the same. It should be noted that as long as there is no structural conflict, any of the embodiments and any of the technical features thereof may be combined with one another, and the technical solutions obtained therefrom all fall within the scope of the present disclosure.

The present disclosure provides an array substrate. As shown in FIGS. 3, 4, and 5, the array substrate comprises data lines 3 and an overcoat layer 1 located above the data lines 3. In a non-display area of the array substrate, a gap is formed in the overcoat layer 1, for matching a sealant. A color barrier layer 8 covering the data lines 3 is formed in the gap. The color barrier layer 8 has a surface lower than a surface of the overcoat layer 1.

In the present embodiment, the data lines 3 located at the gap are provided thereon with the insulative color barrier layer 8. The color barrier layer 8 covers said data lines 3 located at the gap, thus isolating a transparent conductive material 2 left in the gap totally from said data lines 3, and further preventing said transparent conductive material 2 from causing a short circuit between said data lines 3 after a common electrode and a pixel electrode are formed, thereby guaranteeing the display effect of the display device.

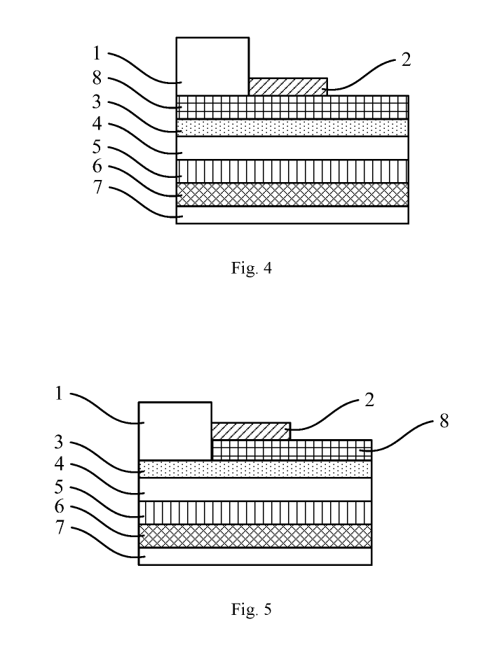

Specific illustration will be provided by taking an array substrate provided with a low temperature poly-silicon (LTPS) thin film transistor (TFT) as an example. On a base substrate 7, a light shield layer is first formed, and then on the light shield layer, a butter layer 6 and amorphous silicon are formed. After that, the amorphous silicon is transformed into low temperature poly-silicon to form an active layer by means of excimer laser annealing method. Then, on the active layer, a gate insulator layer 5, a gate, an inter level dielectric layer 4, and data lines 3 are formed. As shown in FIG. 4 or 5, at a position corresponding to the gap of the overcoat layer 1, there are the butter layer 6, the gate insulator layer 5, and the inter level dielectric layer 4. Next, for a display device provided with R (red) pixels, blue (B) pixels, and G (green) pixels, the R pixels, G pixels, and B pixels can be formed on the array substrate of the display device by forming a red color filter, a green color filter, and a blue color filter. At least one of a red color barrier layer, a green color barrier layer, and a blue color barrier should be kept in the gap. The color barrier layer 8 covers the exposed data lines 3. Finally, structures such as the overcoat layer 1, the gap, a common electrode, and a passivation layer, and a pixel electrode are formed.

A red, green, and blue color filter layer is transferred to an array substrate, and a black matrix is kept on a substrate assembled together with the array substrate. This technology is called color filter on array (COA) technology. In the embodiment of the present disclosure, the color barrier layer 8 covers the data lines 3 in the gap, and therefore can prevent a transparent conductive material 2 from causing a short circuit between the data lines 3 when a common electrode and a pixel electrode are formed.

Accordingly, on a substrate assembled together with the array substrate, a black matrix and a post spacer are formed in turn, and it is not necessary to form an overcoat layer, by means of which light loss resulting from absorption of the overcoat layer can be reduced, thus improving light utilization rate of the display device.

Further, the color filer layer and the black matrix originally formed on the color filter substrate can be both placed on the array substrate, which is helpful to improve accuracy of contraposition of the color filer layer and the black matrix, reduce size of pixel units on the array substrate and width of the black matrix, improve the light transmittance and resolution of the display device, and reduce light leakage of the display device at a wide viewing angle.

In the case that the black matrix is also transferred to the array substrate, since the black matrix is also made of an insulative material, in the present embodiment, the black matrix can also act as the color barrier layer 8 covering the exposed data lines.

It should be noted that in the present embodiment, though the color barrier layer 8 is formed prior to the overcoat layer 1, etching gases used in respective photo engraving processes for forming the overcoat layer 1 and the color barrier layer 8 are different because the color barrier layer 8 and the overcoat layer 1 are different in main components. When the gap is formed in the overcoat layer 1, the etching gas will have no effect on the color barrier layer 8 even if it contacts the color barrier layer 8. Therefore, the color barrier layer 8 covering the data lines 3 can successfully ensure that the data lines 3 can be safely protected, instead of being exposed by the gap after the overcoat layer 1 and the gap are formed.

To better improve the light transmittance of the display device and reduce light leakage of the display device at a wide viewing angle, the color filer layer may comprise a transparent color barrier layer 8, which together with the red color barrier layer, blue barrier layer, and green color barrier layer 8, is arranged on the color filter substrate or the array substrate in an array. The transparent color barrier layer 8 can also be kept in the gap, covering the data lines 3 in the gap.

Therefore, in the present embodiment, the color barrier layer 8 kept in the gap may comprise at least one of a black color barrier layer, a red color barrier layer, a green color barrier layer, a blue color barrier layer, and a color less color barrier layer.

In a specific example of the present embodiment, as shown in FIG. 4, the color barrier layer 8 can be formed between the overcoat layer 1 and the data lines 3, and the overcoat layer 1 can be formed directly on the color barrier layer 8. In this case, a depth of the gap will be dependent mainly on a thickness of the overcoat layer 1. To guarantee insulating effect of the color barrier layer 8 on the data lines 3, the thickness of the color barrier layer 8 can be increased as large as possible. For example, the color barrier layer 8 formed in the gap can comprise three layers, namely, a red color barrier layer, a green color barrier layer, and a blue color barrier layer.

Generally, the color barrier layer 8 can have a thickness ranging from 1 μm to 5 μm, and the overcoat layer can have a thickness ranging from 1 μm to 6 μm. For instance, if the thickness of the color barrier layer 8 comprising the red color barrier layer, the green color barrier layer, and the blue color barrier layer is 2 μm, the thickness of the overcoat layer 1 can be be 3 μm. Since the etching gases used for forming the overcoat layer 1 and the color barrier layer 8 are different, the etching gas used for forming the gap will not be able to etch the color barrier layer 8, and the depth of the gap can be at most 3 μm.

In another specific example of the present embodiment, as shown in FIG. 5, after the color barrier layer 8 is formed, a part of the color barrier layer 8 along an outer edge of the gap can be removed, thus enabling the overcoat layer 1 to be disposed directly on the data lines 3. In other words, the overcoat layer 1 and the color barrier layer 8 are located at a same layer on the data lines. In this case, the depth of the gap is dependent on a difference between the thickness of the overcoat layer 1 and the thickness of the color barrier layer 8. In order to ensure that, when the array substrate and the color filter substrate are assembled together, the depth of the gap, in view of the adhesiveness of the sealant, can meet the requirement of sealing an array substrate and a color filter substrate assembled together with the array substrate, a surface of the color barrier layer 8 should be at least 0.5 μm lower than that of the overcoat layer 1.

Obviously, the number of the color barrier layer 8 disposed in the gap is mainly dependent on the thickness of each of the color barrier layers 8 and the overcoat layer 1. For example, if the thickness of the overcoat layer is 5 μm, and the thickness of each of the color barrier layers 8 (including a red color barrier layer, a green color barrier layer, a blue color barrier layer, a black color barrier layer, and a transparent color barrier layer) is 2 μm, at most two color barrier layers 8 can be provided. That is, the thickness of the color barrier layers 8 is 4 μm, and the surface of the color barrier layers 8 is 1 μm lower than that of the overcoat layer 1.

The present disclosure further provides a display device which comprises any one of the above array substrates, and a color filter substrate assembled together with the array substrate. Specifically, the display device can be a product or a component having a display function, for example, a liquid crystal panel, a liquid crystal TV, a liquid crystal display device, a digital photo frame, a mobile phone, a tablet PC, etc.

The above embodiments are described only for better understanding, rather than restricting the present disclosure. Anyone skilled in the art can make amendments to the implementing forms or details without departing from the spirit and scope of the present disclosure. The scope of the present disclosure should still be subject to the scope defined in the claims.

1. An array substrate, comprising data lines and an overcoat layer located above the data lines,
wherein in a non-display area of the array substrate, a gap is formed in the overcoat layer for matching a sealant, and a color barrier layer covering the data lines is formed in the gap, the color barrier layer having a surface lower than a surface of the overcoat layer.

2. The array substrate according to claim 1, wherein the color barrier layer is located between the overcoat layer and the data lines.

3. The array substrate according to claim 1, wherein the color barrier layer and the overcoat layer are located at a same layer on the data lines.

4. The array substrate according to claim 1, further comprising, at a position corresponding to the gap of the overcoat layer, and between the data lines and a base substrate, from bottom to top, a buffer layer, a gate insulator layer, and an inter level dielectric layer.

5. The array substrate according to claim 4, wherein the color barrier layer comprises at least one of a red color barrier layer, a green color barrier layer, a blue color barrier layer, and a transparent color barrier layer.

6. The array substrate according to claim 5, wherein the surface of the color barrier layer is at least 0.5 μm lower than that of the overcoat layer.

7. The array substrate according to claim 6, wherein the color barrier layer has a thickness ranging from 1 μm to 5 μm.

8. The array substrate according to claim 7, wherein the overcoat layer has a thickness ranging from 1 μm to 6 μm.

9. A display device, comprising an array substrate and a color filter substrate assembled with the array substrate,
wherein the array substrate comprises data lines and an overcoat layer located above the data lines; and
wherein in a non-display area of the array substrate, a gap is formed in the overcoat layer, for matching a sealant, and a color barrier layer covering the data lines is formed in the gap, the color barrier layer having a surface lower than a surface of the overcoat layer.

10. The display device according to claim 9, wherein the color barrier layer is located between the overcoat layer and the data lines.

11. The display device according to claim 9, wherein the color barrier layer and the overcoat layer are located at a same layer on the data lines.

12. The display device according to claim 9, further comprising, at a position corresponding to the gap of the overcoat layer, and between the data lines and a base substrate, from bottom to top, a buffer layer, a gate insulator layer, and an inter level dielectric layer.

13. The display device according to claim 12, wherein the color barrier layer comprises at least one of a red color barrier layer, a green color barrier layer, a blue color barrier layer, and a colourless color barrier layer.

14. The display device according to claim 13, wherein the surface of the color barrier layer is at least 0.5 μm lower than that of the overcoat layer.

15. The display device according to claim 14, wherein the color barrier layer has a thickness ranging from 1 μm to 5 μm.

16. The array substrate according to claim 15, wherein the overcoat layer has a thickness ranging from 1 μm to 6 μm.
